(19) United States
(12) Patent Application Publication
(10) Pub. No.: US 2025/0240949 A1
(43) Pub. Date: Jul. 24, 2025

(54) 3D MEMORY ARRAY ARCHETECTURE AND METHOD OF FABRICATING THE SAME

(71) Applicant: Taiwan Semiconductor Manufacturing Company, Ltd., Hsinchu (TW)

(72) Inventors: Chi Lo, Hsinchu (TW); Yi-Ching Liu, Hsinchu (TW); Yih Wang, Hsinchu (TW)

(21) Appl. No.: 18/660,757

(22) Filed: May 10, 2024

Related U.S. Application Data
(60) Provisional application No. 63/622,313, filed on Jan. 18, 2024.

(51) Int. Cl. H10B 12/00; G11C 11/408; G11C 11/4091

(52) U.S. Cl. CPC H10B 12/50; H10B 12/02; H10B 12/315; G11C 11/4087; G11C 11/4091

(57) ABSTRACT

A memory device includes a plurality of memory arrays, a plurality of first sense amplifiers, and a plurality of multiplexers. Each of the plurality of memory arrays includes a plurality of memory cells that are formed in a respective one of a plurality of metallization layers, which are disposed over a substrate. Each of the plurality of first sense amplifiers and a corresponding one of the memory arrays are formed in a respective one of the metallization layers. Each of the plurality of multiplexers, a corresponding one of the memory arrays, and a corresponding one of the first sense amplifiers are formed in the respective one of the metallization layers. Thus, the peripheral area of the memory device is reduced, thereby advantageously achieving higher density thereof.

### CROSS-REFERENCE TO RELATED APPLICATION

This application claims priority to and the benefit of U.S. Provisional Application No. 63/622,313, filed Jan. 18, 2024, which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device including a number of back-end-of-line (BEOL) memory cells in accordance with some embodiments.

FIG. 2 illustrates a circuit diagram of one of the BEOL memory cells of the memory device of FIG. 1 in accordance with some embodiments.

FIG. 3 illustrates a perspective view of the BEOL memory cell of FIG. 2 in accordance with some embodiments.

FIG. 4 illustrates a perspective view of a memory array including a number of the BEOL memory cells of FIG. 2 in accordance with some embodiments.

FIG. 5 illustrates a perspective view of a memory advice (being formed) including a number of the BEOL memory cells of FIGS. 2 and 3 in accordance with various embodiments.

FIG. 6 illustrates a perspective view of a memory advice including a number of the BEOL memory cells of FIG. 2 in accordance with some embodiments.

FIG. 7 illustrates a block diagram regarding a boundary portion of a metallization layer of the memory device of FIG. 6 in accordance with some embodiments.

FIG. 8 illustrates a flow chart of an example method of fabricating a memory device of FIG. 6 in accordance with some embodiments.

FIG. 9 illustrates a flow chart of an example method of operating a memory device of FIG. 6 in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many electronic products need various amounts of memory devices (e.g., memory bit cells or memory cells) to store information, e.g., data. One common configuration of the memory bit cells consist of an access transistor and a capacitor electrically connected in series, which is sometimes referred to as a one-transistor-one-capacitor (1T1C) cell. Data can be either stored in the memory cells during a write mode, or data may be retrieved from the memory cells during a read mode. Source/drain terminals of the access transistors of the memory cells are connected to internal signal lines, sometimes referred to as bit or digit lines. Gate terminals of the access transistors of the memory cells are connected to addressing lines, sometimes referred to as word lines. The word line selects an access transistor to be turned on, and the bit line is thus coupled to a corresponding capacitor via an induced (e.g., turned on) channel of the access transistor.

A thin-film transistor (TFT) is a kind of field-effect transistor including a channel layer, a gate terminal, and source and drain terminals, over a supporting but non-conducting substrate. A TFT differs from a conventional transistor, where a channel of the conventional transistor is typically formed within, from, or based on a substrate, such as a silicon substrate. TFTs have emerged as an attractive option to fuel Moore's law by integrating TFTs in a back-end-of-line (BEOL) network, while leaving the silicon substrate areas for high-speed transistors. A TFT may be used as the access transistor for a memory cell. A memory device including such BEOL memory cells is sometimes referred to as a BEOL memory device.

However, current designs and implementations of BEOL memory devices still face many challenges. For example, a three-dimensional (3D) memory device that implements stacked memory arrays of 1T1C memory cells may need write-back or refresh operations for the memory cells, and thus the stacked memory arrays of the 3D memory device may encounter a word line (WL) decoder overhead when decoding a single WL due to the inclusion of extra layers in the 3D memory device. For example, for 1T1C memory cells, a sense amplifier (SA) is necessary for each bit line (BL) for a destructive read and also for a write-back of storage capacitance charges due to the destructive read.

The present disclosure provides various embodiments of a three-dimensional (3D) memory device. In some embodiments of the present disclosure, the 3D memory device includes a plurality of memory arrays, a plurality of first sense amplifiers, and a plurality of multiplexers. Each of the plurality of memory arrays includes a plurality of memory cells that are formed in a respective one of a plurality of metallization layers, which are disposed over a substrate. Each of the plurality of first sense amplifiers and a corresponding one of the memory arrays are formed in a respective one of the metallization layers. Each of the plurality of multiplexers, a corresponding one of the memory arrays, and a corresponding one of the first sense amplifiers are formed in the respective one of the metallization layers. Thus, a peripheral size or area of the memory device is reduced, thereby advantageously achieving higher density thereof.

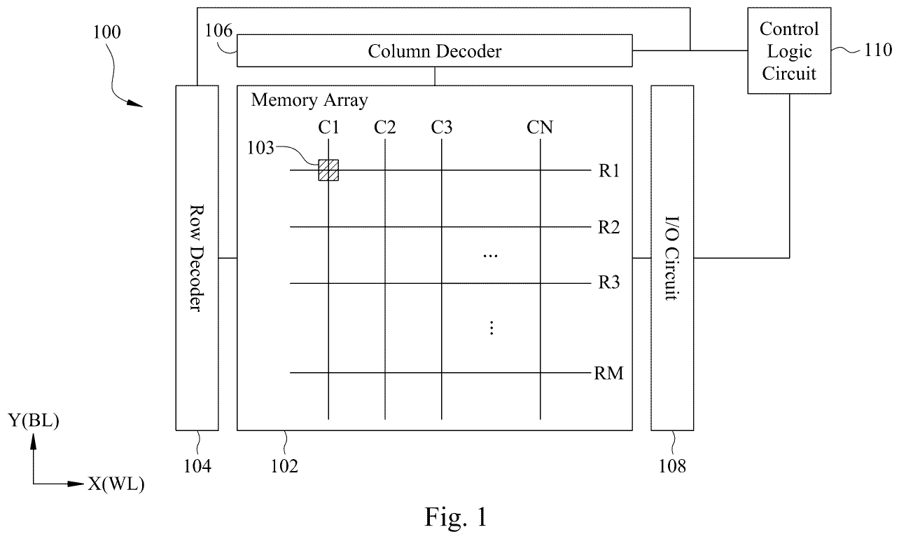

FIG. 1 illustrates an example block diagram of a semiconductor (e.g., memory) device 100 including a number of back-end-of-line (BEOL) memory cells in accordance with various embodiments of the present disclosure. In the illustrated embodiment of FIG. 1, the memory device 100 includes a memory array 102, a row decoder 104, a column decoder 106, an input/output (I/O) circuit 108, and a control logic circuit 110. Despite not being explicitly shown in FIG. 1, the components of the memory device 100 may be operatively coupled to each other and to the control logic circuit 112. For example, the control logic circuit 110, the I/O circuit 108, the column decoder 106, and the row decoder 104 may be electrically coupled to the memory array 102. Although, in the illustrated example of FIG. 1, the component are shown as separate blocks for the purpose of clear illustration, in other embodiments, some or all of the components as shown in FIG. 1 may be integrated together. For example, the memory array 102 may include an embedded I/O circuit 108.

In some embodiments of the present disclosure, the memory array 102 is a hardware component that stores data. In one aspect of the present disclosure, the memory array 102 is embodied as a semiconductor memory device. The memory array 102 includes a number of memory cells (or otherwise storage units) 103. The memory array 102 includes a number of rows R₁, R₂, R₃ . . . . R_{M}, each extending in a first direction (e.g., the X-direction) and a number of columns C₁, C₂, C₃ . . . . C_{N}, each extending in a second direction (e.g., the Y-direction). Each of the rows/columns may include one or more conductive structures. In some embodiments, each memory cell 103 is arranged at the intersection of a corresponding row and a corresponding column, and can be operated according to voltages or currents through the respective conductive structures of the column and the row.

In some embodiments of the present disclosure, the row decoder or X decoder (XDEC) 104 is a hardware component that can receive a row address of the memory array 102 and assert a conductive structure (e.g., a word line) at that row address. The column decoder or Y decoder (YDEC) 106 is a hardware component that can receive a column address of the memory array 102 and can assert one or more conductive structures (e.g., a bit line or a source line) at that column address. The I/O circuit 108 is a hardware component that can access (e.g., read or program) each of the memory cells 103 that is asserted through the row decoder 104 and column decoder 106. The control logic circuit (or controller) 110 is a hardware component that can control the coupled components (e.g., components 102 through 108).

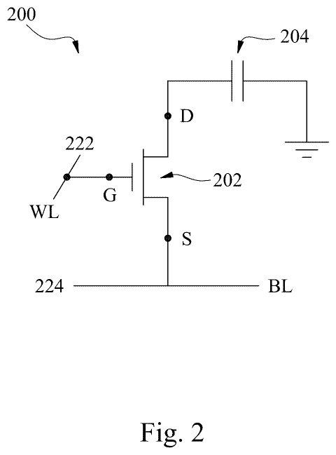

FIG. 2 illustrates an example configuration of a memory cell 200 that is an implementation of the memory cells 103 as shown in FIG. 1 in accordance with various embodiments of the present disclosure. As shown in FIG. 2, the memory cell 200 is implemented as a one-transistor-one-capacitor (1T1C) configuration, includes an access transistor 202 and a capacitor 204 coupled to each other in series. Specifically, the access transistor 202 may have one source/drain terminal (e.g., drain terminal “D”) electrically coupled to one terminal of the capacitor 204, another source/drain terminal (e.g., drain terminal “S”) electrically coupled to a bit line (BL) 224, and a gate terminal (e.g., “D”) electrically coupled to a word line (WL) 222. The other terminal of the capacitor 204 may be grounded.

In some embodiments of the present disclosure, the memory cell 200 may be operatively configured as a dynamic random access memory (DRAM) cell. However, it should be understood that the memory cell 200 can be operatively configured as any of various other memory configurations, such as a ferroelectric random access memory (FeRAM) cell, a spin-transfer torque magnetic random access memory (STT-RAM) cell, and a phase change random access memory (PCRAM) cell, while remaining within the scope of the present disclosure.

To access (e.g., program or read) the memory cell 200, the access transistor 202 (if embodied as an n-type transistor) is turned on by applying a voltage signal, corresponding to a logic high state, through the word line WL 222, to the gate terminal of the access transistor 202. Concurrently or subsequently, a signal (e.g., a pulse signal) is applied on the source/drain terminal D of the access transistor 202 through the bit line BL 224. With the access transistor 202 turned on, the memory cell 200 is allowed to be accessed. For example, a path (e.g., a programming or reading path) can be provided from the BL 224, through the access transistor 202, to the capacitor 204.

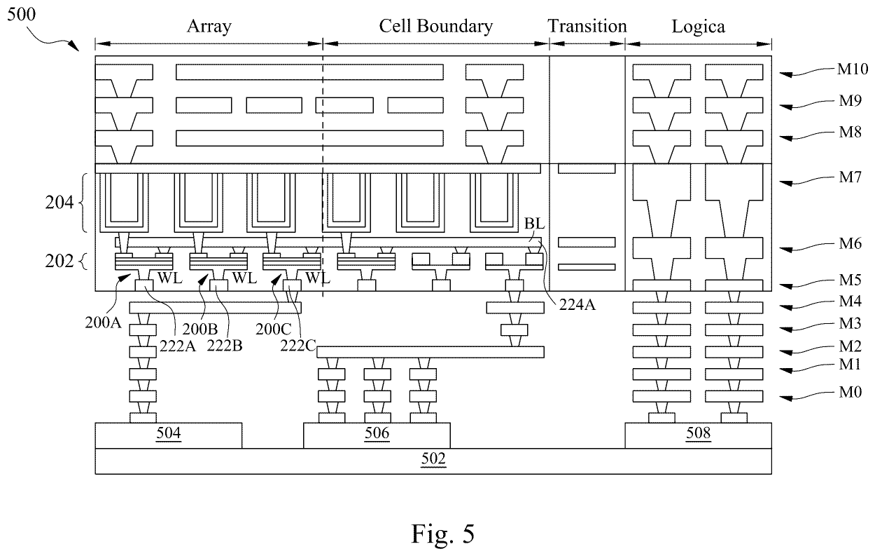

In accordance with various embodiments of the present disclosure, the access transistor 202 and the capacitor 204 are formed on the same side of a semiconductor substrate, e.g., the major frontside of a semiconductor substrate. Further, the access transistor 202 and the capacitor 204 are both formed across one or more metallization layers that are disposed above the frontside surface of the semiconductor substrate, e.g., M0, M1, M2, M3, M4, M5, M6, M7, M8, M9, M10 etc. Each of the metallization layers includes a number of conductor lines (e.g., metal lines) embedded in one or more inter-layer dielectrics (ILDs) or inter-metal dielectrics (IMDs). The ILD/IMDs can include one or more of a low-k dielectric layer (i.e., a dielectric with a dielectric constant less than about 3.9), an ultra low-k dielectric layer, or an oxide (e.g., silicon oxide) layer. Such metallization layers may be collectively referred to as a back-end-of-line (BEOL) network. Accordingly, the memory cell 200 is sometimes referred to as a BEOL memory cell 200. More details about the BEOL network will be described with respect to in FIG. 5.

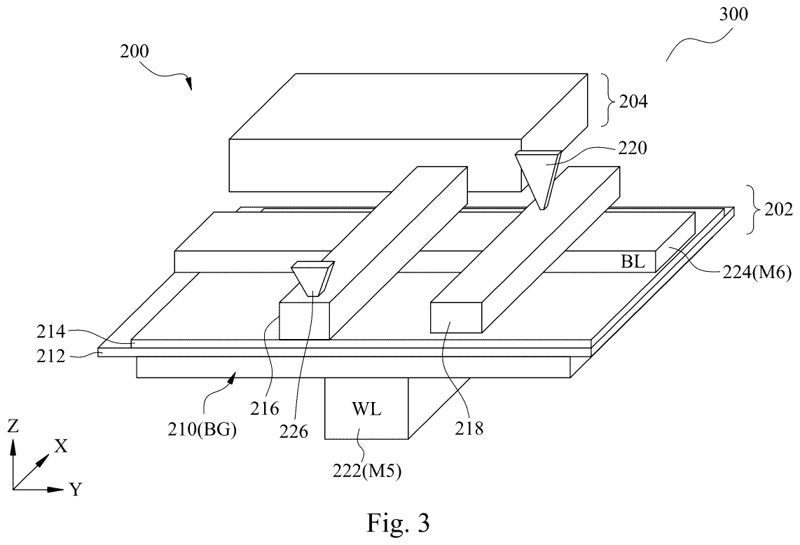

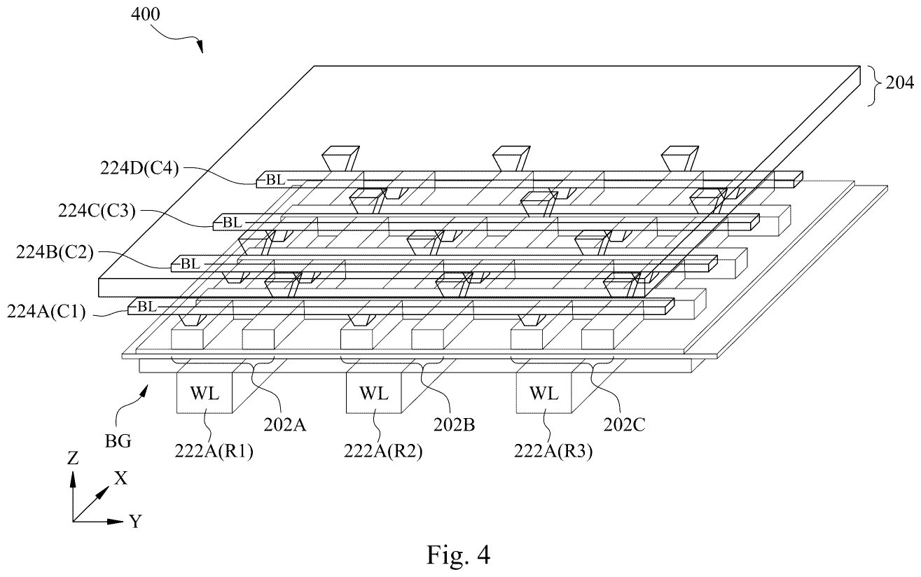

FIG. 3 illustrates a perspective view 300 of an example configuration of such a BEOL memory cell 200 (being formed) in accordance with various embodiments, and FIG. 4 illustrates a perspective view of a memory array 400 including a plural number of the formed BEOL memory cells 200 in accordance with various embodiments. It should be noted that the perspective views of FIGS. 3 and 4 are simplified, and thus one or more components may not be expressly shown.

Referring first to FIG. 3, the access transistor 202 can be formed as a thin-film transistor (TFT) structure in some embodiments. Furthermore, the access transistor 202 can be configured as a back-gate transistor in some embodiments. For example, as shown in FIG. 3, the access transistor 202 may include a first conductor structure 210, a dielectric layer 212 disposed over the first conductor structure 210, a semiconductive-behaving layer 214 disposed over the dielectric layer 212, and a second conductor structure 216 and a third conductor structure 218 disposed over the channel layer 214. The first conductor structure 210 may operatively serve as a gate terminal of the access transistor 202 (sometimes referred to as a back gate “BG”), the dielectric layer 212 may operatively serve as a gate dielectric of the access transistor 202, the semiconductive-behaving layer 214 may operatively serve as a channel of the access transistor 202, and the second conductor structures 216 and 218 may operatively serve as a source terminal (sometime referred to as “S”) and a drain terminal (sometime referred to as “D”) of the access transistor 202.

Each of the components (e.g., 210 to 218) of the access transistor 202 may be formed across one of the metallization layers or between two neighboring metallization layers, e.g., between metallization layers M5 and M6. The conductor structures 210, 216, and 218 may be made of tungsten, copper, gold, cobalt, ruthenium, or combinations thereof. The dielectric layer 212 may include one or more of a high-k dielectric layer (i.e., a dielectric with a dielectric constant greater than about 3.9) such as, for example, a metal oxide or a silicate of hafnium, aluminum, zirconium, lanthanum, magnesium, barium, titanium, lead, the like, or combinations thereof. The semiconductive-behaving layer 214 may include a semiconductive-behaving oxide material such as, for example, IGZO, InZnO, InSnO, SnO₂, MgAlZnO, CuO, SnO, oxides of the Delafossite group Cu—X—O with or without doping, or combinations thereof.

Although not expressly shown in FIG. 3, the capacitor 204 can be formed as a metal-insulator-metal (MIM) or metal-oxide-metal (MOM) structure disposed above the access transistor 202. The capacitor 204 may be electrically coupled to the access transistor 202 (or its drain terminal, e.g., the conductor structure 218) through a via structure 220. For example, the capacitor 204 may include a capacitor dielectric layer interposed between a bottom electrode and a top electrode. The bottom/top electrode may include tungsten, copper, gold, cobalt, ruthenium, or combinations thereof; and the capacitor dielectric layer interposed therebetween may include one or more of a high-k dielectric layer such as, for example, a metal oxide or a silicate of hafnium, aluminum, zirconium, lanthanum, magnesium, barium, titanium, lead, the like, or combinations thereof. With respect to the access transistor 202 formed between M5 and M6, each of the components of the capacitor 204 may be formed within another of the metallization layers or between two neighboring metallization layers above metallization layer M6, e.g., between metallization layers M6 and M7.

Still referring to FIG. 3, the gate terminal of the access transistor 202 (e.g., the conductor structure 210) is coupled to a WL 222 through a via structure (not shown). For example, the WL 222 may be formed within the metallization layer below the access transistor 202, e.g., metallization layer M5, and extend along a first lateral direction (e.g., the X-direction). The source terminal of the access transistor 202 (e.g., the conductor structure 216) is coupled to a BL 224 through a via structure 226. For example, in FIG. 3, the BL 224 may have at least one portion formed within the metallization layer above the transistor 202, e.g., metallization layer M6, and extending along a second lateral direction (e.g., the Y-direction). According to various embodiments of the present disclosure, the BL 224 can include a plural number (e.g., 2) of end portions in one metallization layer that are physically spaced from each other but electrically coupled to each other through one or more conductor structures disposed across one or more other metallization layers, which will be discussed in further detail with respect to FIG. 5.

Referring then to FIG. 4, in some embodiments, the memory array 400 includes a number of such BEOL memory cells 200 that are arranged over multiple rows and columns. Respective transistors, e.g., 202A, 202B, and 202C, of some of the BEOL memory cells 200 are shown, while respective capacitors of the memory cells 200 are collectively shown as capacitor 204. The memory array 400 further includes WLs 222, such as 222A, 222B, and 222C (which may correspond to rows R₁, R₂, and R₃, respectively), and BLs 224, such as 224A, 224B, 224C, and 224D (which may correspond to columns C₁, C₂, C₃, and C₄, respectively). In some embodiments, the WLs 222, e.g., 222A to 222C, may be disposed in metallization layer M5 and extend in a first lateral direction (e.g., the X-direction); and the BLs 224, e.g., 224A to 224D, may each include some portions disposed in metallization layer M6 and extending in a second lateral direction (e.g., the Y-direction) perpendicular to the first lateral direction. In the example embodiment of FIG. 4, the memory cells of the memory array 400 may share a common back gate BG, with each subset of the memory cells disposed along a corresponding row sharing a common WL and each subset of the memory cells disposed along a corresponding column sharing a common BL.

FIG. 5 illustrates a perspective view of a 3D memory advice 500 (being formed) including a number of the BEOL memory cells 200 discussed above with respect to FIGS. 2-4 in accordance with various embodiments of the present disclosure. For example, the 3D memory advice 500 can include the memory array 400 of FIG. 4. In addition, the 3D memory advice 500 in FIG. 5 can also include a number of other structures operatively serving as the components, such as a row decoder 104, a column decoder 106, an input/output (I/O) circuit 108, and a control logic circuit 110, as discussed in FIG. 1.

As shown, the memory device 500 may be divided into a number of portions, sections, or regions that are laterally arranged with respect to one another, e.g., an array portion, a boundary portion, a transition portion, and a logic portion. These portions may be formed over a substrate 502. Along a major (front) surface of the substrate 502, a number of first transistors 504, second transistors 506, and third transistors 508 are formed in the array portion, the boundary portion, and the logic portion, respectively, that are formed as a part of a front-end-of-line (FEOL) network. The transistors 504, 506 and 508 may form a part of a front-end-of-line (FEOL) network. Over the FEOL network, the memory device 500 includes a number of metallization layers, e.g., M0, M1, M2, M3, M4, M5, M6, M7, M8, M9, and M10, that are formed as a part of a back-end-of-line (BEOL) network.

In the array portion, the memory device 500 may include a number of BEOL memory cells 200, such as 200A, 200B, and 200C. Each of the memory cells 200 consists of a respective transistor 202 that is formed between metallization layers M5 and M6, and a respective capacitor 204 that is formed between metallization layers M6 and M7. In some embodiments, the BEOL memory cells 200 can be formed as a memory array, which can be operatively accessed through WLs 222, such as 222A, 222B, and 222C, and BLs 224, such as 224A. In the cross-sectional view of FIG. 5, the WLs 222A, 222B, and 222C are disposed in metallization layer M5, and the BL 224A is disposed in metallization layer M6. Further, the first transistors 504, configured in the array portion, may operatively serve as one or more WL drivers for the memory array (e.g., part of the row decoder 104 of FIG. 1). The second transistors 506, configured in the boundary portion, may operatively serve as one or more sensing amplifiers (SAs) for the memory array (e.g., part of the I/O circuit 108 of FIG. 1). The third transistors 508, configured in the logic portion, may operatively serve as one or more control circuits for the memory array (e.g., part of the control logic circuit 110 of FIG. 1).

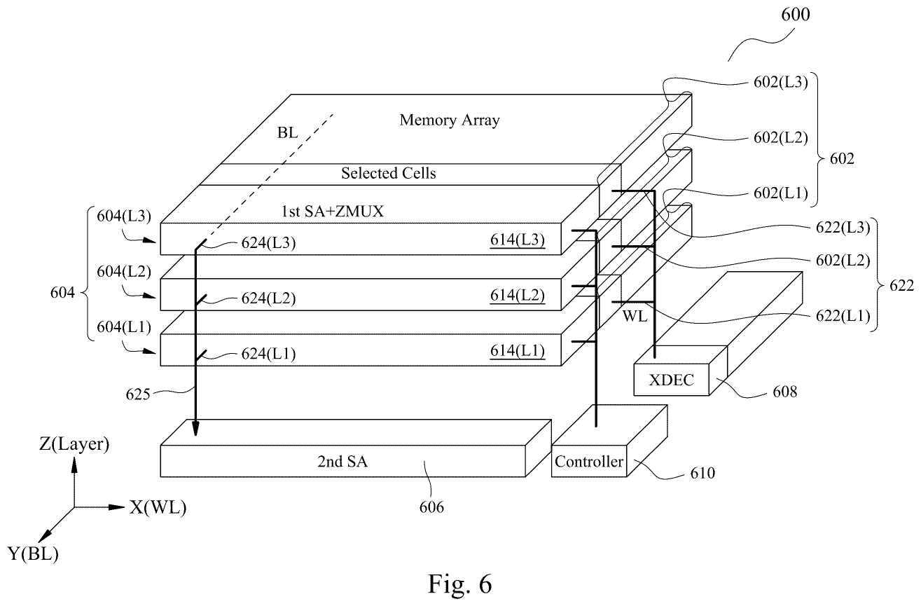

FIG. 6 illustrates a perspective view of a 3D memory advice 600 including a number of the BEOL memory cells 200 of FIG. 2 (corresponding to 103 in FIG. 1) in accordance with some embodiments of the present disclosure. Referring to FIG. 6, in some embodiments, the 3D memory advice 600 includes a plurality of metallization layers 604 (such as 604(L1), 604(L2), and 604(L3)) that are disposed over a substrate (e.g., 502 in FIG. 5). Although three metallization layers 604 are shown in FIG. 6, a 3D memory advice 600 including multiple number different from three of metallization layers remain within the scope of the present disclosure. The 3D memory advice 600 further includes a plurality of memory arrays 602 (such as 602(L1), 602(L2), and 602(L3)) that are disposed in first ones of the metallization layers 604, a plurality of word lines (WLs) 622 (such as 622(L1), 622(L2), and 622(L3)) that are disposed in second ones of the metallization layers 604, a plurality of bit lines (BLs) 624 (such as 624(L1), 624(L2), and 624(L3)) that are disposed in third ones of the metallization layers 604, one or more word line decoders 608 that are formed over the substrate 502, and a controller 610 that is formed over the substrate 502. In some embodiments, each memory array (e.g., 602(L1)) of the plurality of memory arrays 602 is disposed in a respective metallization layer 604 (e.g., 604(L1)) and includes a plurality of memory cells (e.g., 200 in FIG. 2). Each memory cell 200 in each memory array 602 (e.g., 602(L3)) includes an access transistor 202 and a capacitor 204 in FIG. 2.

As shown in FIG. 6, in some embodiments of the present disclosure, the plurality of word lines (WLs) 622 are disposed in parallel rows extending a X-direction, and respectively disposed some (e.g., 604(L1), 604(L2), and 604(L3)) of the plurality of metallization layers 604. In some embodiments, a row of WLs 622 (e.g., 622(L1), 622(L2), and 622(L3) respectively disposed in some metallization layers (e.g., 604(L1), 604(L2), and 604(L3)) of the plurality of metallization layers 604 are commonly coupled to a word line (WL) decoder (or XDEC) 608, and thus can be commonly selected and decoded by the WL decoder 608. As such, the peripheral area and thus the chip area of the 3D memory device 600 is reduced, thereby advantageously achieving higher density of the 3D memory device 600. Although a single WL decoder 608 of the memory advice 600 is illustrated in FIG. 6, it is appreciated that a memory advice including more than one WL decoder 608 remains with the scope of the present disclosure.

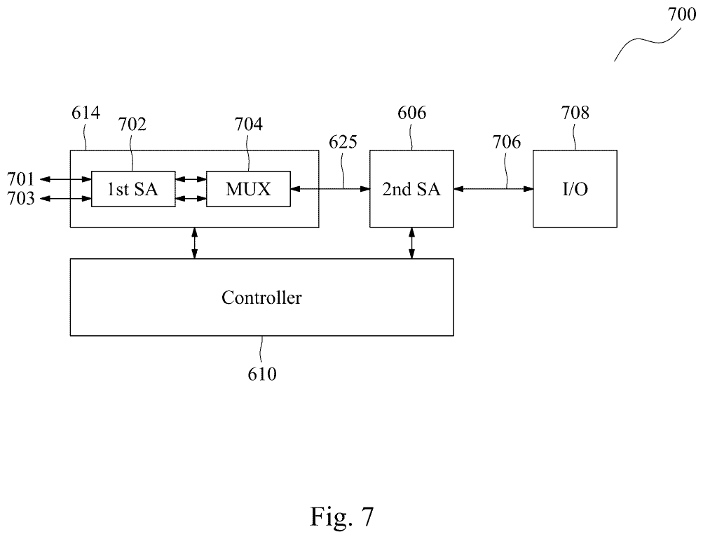

Also as shown in FIG. 6, in some embodiments of the present disclosure, the 3D memory advice 600 further includes a plurality of boundary portions 614 (e.g., 614(L1), 614(L2), and 614(L3)) that are disposed in boundary regions of the plurality of metallization layers 604 (e.g., 604(L1), 604(L2), and 604(L3)) adjacent to the plurality of memory arrays 602 in the plurality of metallization layers 604, respectively. Details about the boundary portions 614 will be described with respect to FIG. 7.

FIG. 7 is a block diagram 700 illustrating an example one of the boundary portions 614 of the 3D memory device 600 of FIG. 6 in accordance with some embodiments of the present disclosure. Referring to FIGS. 6 and 7, each boundary portion 614 (e.g., 614(L3)) in a respective metallization layer 604 (e.g., 604(L3)) includes a first sense amplifier (SA) 702 and a multiplexer (MUX) 704 that are coupled to each other in series. As such, due to the stacking of the first SAs 702 and the integration of the first SAs 702 with the 3D memory arrays 602, the chip area and the peripheral area can be reduced, the routing can be simplified, and the memory density can be advantageously enhanced.

In some embodiments, as shown in FIGS. 6 and 7, the first SA 702 of each boundary portion 614 (e.g., 614(L3)) in the respective metallization layer 604 (e.g., 604(L3)) is coupled to and thus capable to access all the BLs 624 (e.g., 624(L3)) in the respective metallization layer 604(L3). In some embodiments, the first SA 702 is coupled to the controller 610 through the MUX 704. In some embodiments, the first SA 702 receives a BL signal 701 from a BL 624 and a reference signal 703, processes the received BL signal 701 and reference signal 703, and outputs a processed signal to a common second SA 606.

In some embodiments of the present disclosure, as shown in FIGS. 6 and 7, the controller 610 is coupled to a plurality of MUXs 704 respectively in the plurality of metallization layers 604 and configured to transmit a control signal indicative of one of the plurality of metallization layers to be selected or asserted. As such the controller 610 is able to select the respective metallization layer (e.g., 604(L3)) from the plurality of metallization layer 604, and thus all the BLs 624 (e.g., 624(L3)) of the selected respective metallization layer (e.g., 604(L3)) are accessible. In some embodiments, the first SA 702, the MUX 704, and the respective memory arrays (e.g., 602(L3)) are formed across the same respective metallization layer 604 (e.g., 604(L3)) in a BEOL network. Thus, the peripheral area of the memory device is reduced, thereby advantageously resulting in higher density of the memory device.

In some embodiments of the present disclosure, as shown in FIGS. 6 and 7, the first SA 702 in a respective metallization layer 604 (e.g., 604(L3)) is coupled to a common second SA 606 through a global bit line (GBL) 625. In some embodiments, the common second SA 606 is coupled to all of the first SAs 702 respectively in the plurality of metallization layers 604 through the plurality of MUXs 704 respectively in the plurality of metallization layers 604, and commonly through the GBL 625. In some embodiments, as shown in FIG. 7, the first SA 702 receives and processes a BL signal 701 from a BL 624 and a reference signal 703, and outputs a processed signal to a common second SA 606. In some embodiments, as shown in FIG. 7, the second SA 606 processes a received signal from the first SA 703, and transmits an output through a data layer 706 to an input/output (I/O) circuit 708. In some embodiments, the common second SA 606, the controller 610, and the I/O circuit 708 are all formed in a FEOL network of the 3D memory device 600 over a major front surface of the substrate 502 (in FIG. 5).

In some embodiments, the operational processes of the 3D memory advice 600 are as follows: BLs are first developed and sensed by a first SA, a ZMUX (e.g., at layer3) is enabled and outputs data to the second SA via a GBL, and remaining SAs conduct read and write-back operations concurrently. In some embodiments, a first SA operates at the initial stage with direct interaction with the memory cells, while a second SA functions at a subsequent stage, receiving processed signals. The first SA is connected directly to the BLs, where the second SA interfaces with the ZMUX and the GBL. The first SA is primarily involved in the initial sensing and amplification of data from the memory cells, while the second SA focuses on handling the output data from the ZMUX.

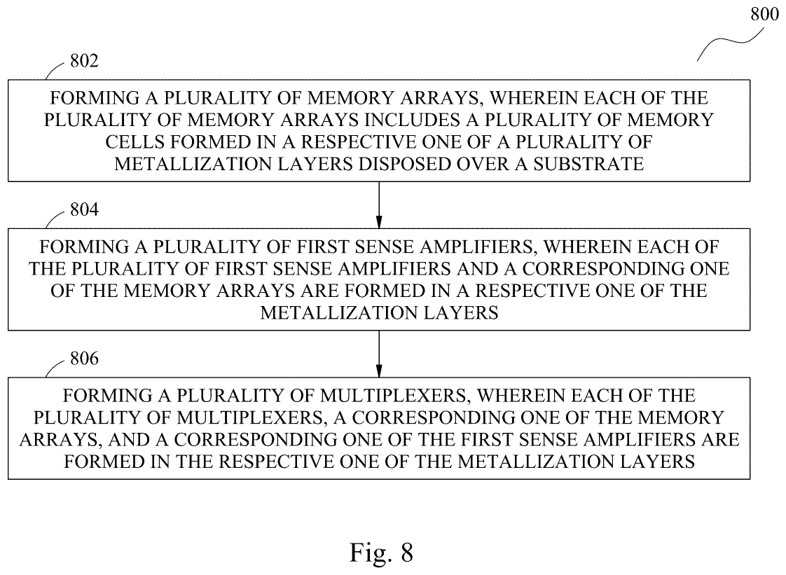

FIG. 8 illustrates a flow chart of an example method 800 of fabricating a 3D memory device 600 of FIG. 6 in accordance with some embodiments of the present disclosure. It should be noted that the method 800 as shown in FIG. 8 is merely an example, and is not intended to limit the present disclosure. Accordingly, it is understood that the order of the operations of the method 800 as shown in FIG. 8 can be changed, for example, additional operations may be provided before, during, and after the method 800 of FIG. 8, and that some operations may only be described briefly herein.

For example, as shown in FIG. 6 (also referring to FIGS. 2, 5 and 7), the 3D memory device 600 that is fabricated by the method 800 may include a plurality of memory arrays 602 (e.g., 602(L1), 602(L2), and 602(L3)) disposed over a substrate (e.g., 502 in FIG. 5), each of the plurality of memory arrays 602 including a plurality of memory cells (e.g., 200 in FIG. 2) formed in a respective one of a plurality of metallization layers 604 (e.g., 604(L1), 604(L2), and 604(L3)); a plurality of first sense amplifiers (SAs), each (e.g., 702 in FIG. 7) of the plurality of first sense amplifiers and a corresponding one (e.g., 602(L3)) of the memory arrays 602 formed in a respective one (e.g., 604(L3)) of the metallization layers 604; and a plurality of multiplexers (e.g., 704 in FIG. 7). In some embodiments, a corresponding one (704 in FIG. 7) of the plurality of multiplexers, the corresponding one (e.g., 602(L3)) of the memory arrays 602, and a corresponding one (e.g., 702 in FIG. 7) of the first sense amplifiers are formed in the respective one (e.g., 604(L3)) of the metallization layers. Accordingly, operations of the method 800 will be discussed in conjunction with the 3D memory device 600 in FIG. 6.

Referring to FIGS. 6 and 8, the method 800 starts with operation 802 of forming a plurality of memory arrays 602 (e.g., 602(L1), 602(L2), and 602(L3)) disposed over a substrate (502 in FIG. 5). For example, each (e.g., 602(L3)) of the plurality of memory arrays 602 includes a plurality of memory cells (e.g., 200 in FIG. 2) that are formed in a respective one (e.g., 604(L3)) of a plurality of metallization layers 604.

In some embodiments, the substrate 502 may be a semiconductor substrate, such as a bulk semiconductor, a semiconductor-on-insulator (SOI) substrate, or the like, which may be doped (e.g., with a p-type or an n-type dopant) or undoped. The substrate may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments of the present disclosure, the metallization layers 604 each include a number of conductor structures embedded in a corresponding IMD/ILD. The conductor structures can include a number of back-end-of-line (BEOL) conductor lines or islands. Each of the conductor structures can include one or more metal materials such as, for example, tungsten (W), copper (Cu), gold (Au), cobalt (Co), ruthenium (Ru), or combinations thereof. The IMD/ILD, embedding the interconnect structure, can include one or more of a low-k dielectric layer (i.e., a dielectric with a dielectric constant less than about 3.9), an ultra low-k dielectric layer, or an oxide (e.g., silicon oxide).

Next, referring to FIGS. 6, 7 and 8, the method 800 proceeds to operation 804 of forming a plurality of first sense amplifiers (SAs) 702 (in FIG. 7). For example, each first SA 702 of the plurality of first SAs and a corresponding memory array (e.g., 602(L3)) of the memory arrays 602 are formed in a respective metallization layer (e.g., 604(L3)) of the metallization layers 604. Specifically, the first SAs 702 can be formed by some semiconductor fabricating processes, such as photolithography, etching, filling of metal, CMP processes, and the like, or a combination thereof.

Next, referring to FIGS. 6 and 8, the method 800 proceeds to operation 806 of forming a plurality of multiplexers (MUXs) 704 (in FIG. 7). For example, a corresponding MUX 704 of the plurality of MUXs, a corresponding memory array (e.g., 602(L3)) of the memory arrays, and a corresponding first SA 702 of the plurality of first SAs are formed in the respective metallization layer (e.g., 604(L3)) of the plurality of metallization layers. Specifically, the MUXs 704 can be formed by some semiconductor fabricating processes, such as photolithography, etching, filling of metal, CMP processes, and the like, or a combination thereof. As such, due to the architecture and configuration of a first SA and a MUX in each boundary portion in each metallization layer of the plurality of metallization layers, the hookup area and the routing complexity of the 3D memory device are advantageously reduced, thereby resulting in higher density and better performance of the 3D memory device.

In some embodiments, the method 800 further includes an operation of forming a second sense amplifier (SA) 606 over the substrate 502. In some embodiments, the second SA 606 is commonly coupled to all the plurality of first SAs 702 respectively formed in the metallization layers 604 (e.g., 604(L1), 604(L2), and 604(L3)) through a global bit line (GBL) 625. Specifically, the second SAs 606 can be formed by some semiconductor fabricating processes, such as photolithography, etching, filling of metal, CMP processes, and the like, or a combination thereof. In some embodiments, referring to FIG. 6, at first, the second sense amplifier (SA) 606, the controller 610 and the XDEC 608 are formed at a lower metallization layer; secondly, a first memory array 602(L1) of the memory arrays 602 as well as its corresponding first SA and ZMUX are formed at a first metallization layer (e.g., 604(L1)) over the lower metallization layer; thirdly, a second memory array 602(L2) of the memory arrays 602 as well as its corresponding first SA and ZMUX are formed at a second metallization layer (e.g., 604(L2)) over the first metallization layer (e.g., 604(L1)), and so on. As such, the memory arrays 602 as well as their corresponding first SA and ZMUX are formed over the second sense amplifier (SA) 606, the controller 610 and the XDEC 608.

In some embodiments of the present disclosure, the operation 802 of forming the plurality of memory arrays 602 (e.g., 602(L1), 602(L2), and 602(L3)) over the substrate 502 (in FIG. 5) includes operations of forming a plurality of access transistors 202 (in FIG. 2) over first ones of the plurality of metallization layers 604, and forming a plurality of capacitors 204 (in FIG. 2) over second ones of the plurality of metallization layers 604. Each memory array 602 (e.g., 602(L3)) in a respective metallization layer 604 (e.g., 604(L3)) of the plurality of metallization layers 604 (e.g., 604(L1), 604(L2), and 604(L3)) in FIG. 6 includes a plurality of memory cells 200 in FIG. 2. Each memory cell 200 in FIG. 2 includes an access transistor 202 and a capacitor 204. In some embodiments, a first terminal of the capacitor 204 is coupled to a first source/drain terminal of the access transistor 202, a second terminal of the capacitor 204 is grounded, a BL 224 is coupled to a second source/drain terminal of the access transistor 202, and a WL 222 is coupled to a gate terminal of the access transistor 202. Specifically, the access transistors 202 and the capacitors 204 can be formed by some semiconductor fabricating processes, such as photolithography, etching, filling of metal, CMP processes, and the like, or a combination thereof.

In some embodiments of the present disclosure, also referring to FIG. 6, the method 800 further includes an operation of forming a plurality of bit lines (BLs) 624 over third ones of the plurality of metallization layers 604. In some embodiments, the plurality of BLs 624 are respectively coupled to second source/drain terminals of the plurality of access transistors (e.g., 202 in FIG. 2). In some embodiments, the method 800 further includes an operation of forming a plurality of word lines (WLs) 622 over fourth ones of the plurality of metallization layers 604. In some embodiments, the plurality of WLs 622 are respectively coupled to gates of the plurality of access transistors 202. Specifically, the BLs 624 and the WLs 622 can be formed by some semiconductor fabricating processes, such as photolithography, etching, filling of metal, CMP processes, and the like, or a combination thereof.

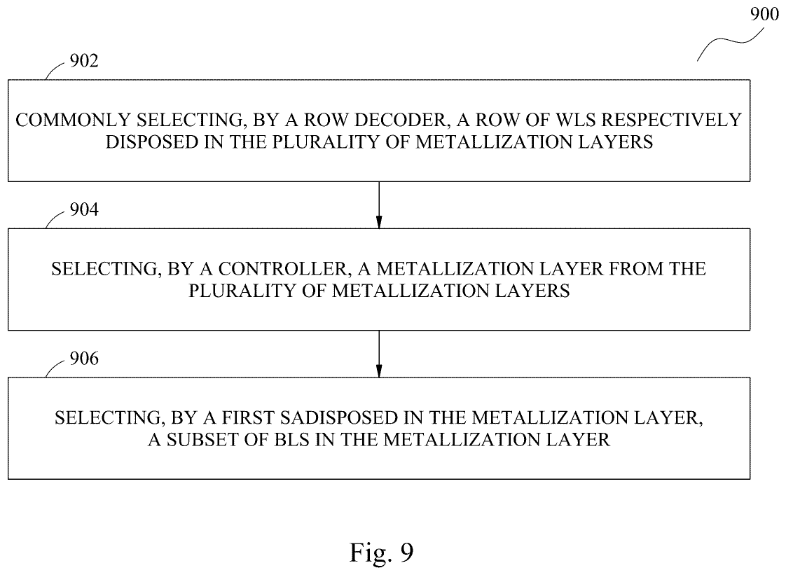

FIG. 9 illustrates a flow chart of an example method 900 of operating a memory device 600 of FIG. 6 in accordance with some embodiments. It should be noted that the method 900 as shown in FIG. 9 is merely an example, and is not intended to limit the present disclosure. Accordingly, it is understood that the order of the operations of the method 900 as shown in FIG. 9 can be changed, for example, additional operations may be provided before, during, and after the method 900 of FIG. 9, and that some operations may only be described briefly herein.

In some embodiments, as shown in FIG. 6 (also referring to FIGS. 2, 5 and 7), the 3D memory device 600 may include a plurality of memory arrays 602 (e.g., 602(L1), 602(L2), and 602(L3)) disposed over a substrate (e.g., 502 in FIG. 5), each of the plurality of memory arrays 602 including a plurality of memory cells (e.g., 200 in FIG. 2) formed in a respective one of a plurality of metallization layers 604 (e.g., 604(L1), 604(L2), and 604(L3)); a plurality of word lines (WLs) 622 (e.g., 622(L1), 622(L2), and 622(L3)) respectively formed over respective ones of the plurality of metallization layers 604; a plurality of bit lines (BLs) 624 (e.g., 624(L1), 624(L2), and 624(L3)) respectively formed over respective ones of the plurality of metallization layers 604; a plurality of first sense amplifiers (SAs), each (e.g., 702 in FIG. 7) of the plurality of first sense amplifiers and a corresponding one (e.g., 602(L3)) of the memory arrays 602 formed in a respective one (e.g., 604(L3)) of the metallization layers 604; and a plurality of multiplexers (e.g., 704 in FIG. 7). In some embodiments, a corresponding one (704 in FIG. 7) of the plurality of multiplexers, the corresponding one (e.g., 602(L3)) of the memory arrays 602, and at least a corresponding one (e.g., 702 in FIG. 7) of the first sense amplifiers are formed in the respective one (e.g., 604(L3)) of the metallization layers. Accordingly, operations of the method 900 will be discussed in conjunction with the 3D memory device 600 in FIG. 6.

Referring to FIGS. 6 and 9, the method 900 starts with operation 902 of commonly selecting, by a row decoder (or XDEC) 608, a row of WLs 622 that are respectively disposed in the plurality of metallization layers 604. For example, a row of WLs 622 (e.g., 622(L1), 622(L2), and 622(L3)) respectively disposed in the plurality of metallization layers 604 (e.g., 604(L1), 604(L2), and 604(L3)) are commonly selected and thus decoded by the WL decoder (or XDEC) 608.

Next, referring to FIGS. 6, 7 and 9, the method 900 proceeds to operation 904 of selecting, by a controller 610, a metallization layer 604 (e.g., 604(L3)) from the plurality of metallization layers 604 (e.g., 604(L1), 604(L2), and 604(L3)). For example, the controller 610 can select the metallization layer 604(L3) from the plurality of metallization layers 604 through a ZMUX 704 disposed in the metallization layer 604(L3).

Next, referring to FIGS. 6, 7 and 9, the method 900 proceeds to operation 906 of selecting, by a first SA 702 disposed in the metallization layer 604(L3), a subset of BLs 624 (e.g., 624(L3)) in the metallization layer 604(L3). For example, the first SA 702 disposed in the metallization layer 604(L3) may select and assert a single BL 624(L3) in the metallization layer 604(L3). As such, a memory cell 200 in FIG. 2 can be selected or asserted through the operations 902, 904 and 906.

After that, the first SA 702 in FIG. 7 can process the signal received from the asserted memory cell 200 in FIG. 2, and output its processing result to a second SA 606 through a global bit line (GBL) 625. The second SA 606 can process the received signal and output its processing result to another device, such as I/O circuit 708 in FIG. 7. Due to the architecture and configuration of at least a first SA and a MUX in each boundary portion in each metallization layer of the plurality of metallization layers, as well the commonly used WL decoders, the hookup area and the routing complexity of the 3D memory device are advantageously reduced, thereby resulting in higher density and better performance of the 3D memory device.

In one aspect of the present disclosure, a memory device is disclosed. The memory device includes a plurality of memory arrays, each of the plurality of memory arrays including a plurality of memory cells formed in a respective one of a plurality of metallization layers disposed over a substrate; a plurality of first sense amplifiers, each of the plurality of first sense amplifiers and a corresponding one of the memory arrays formed in a respective one of the metallization layers; and a plurality of multiplexers, each of the plurality of multiplexers, a corresponding one of the memory arrays, and a corresponding one of the first sense amplifiers formed in the respective one of the metallization layers.

In another aspect of the present disclosure, a memory device is disclosed. The memory device includes a first memory array including a plurality of first memory cells that are disposed in a first one of a plurality of metallization layers disposed over a substrate; a first sense amplifier also disposed in the first metallization layer, and configured to sense first data bits respectively stored in a subset of the first memory cells that are arranged along at least one column of the first memory array; and a first multiplexer also disposed in the first metallization layer, and configured to provide the first sensed data bits to a common sense amplifier upon receiving a first control signal indicative of the first metallization layer, wherein the common sense amplifier is formed along a major surface of the substrate.

In yet another aspect of the present disclosure, a method of fabricating a memory device is disclosed. The method includes forming a plurality of memory arrays, wherein each of the plurality of memory arrays includes a plurality of memory cells formed in a respective one of a plurality of metallization layers disposed over a substrate; forming a plurality of first sense amplifiers, wherein each of the plurality of first sense amplifiers and a corresponding one of the memory arrays are formed in a respective one of the metallization layers; and forming a plurality of multiplexers, wherein each of the plurality of multiplexers, a corresponding one of the memory arrays, and a corresponding one of the first sense amplifiers are formed in the respective one of the metallization layers.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of memory arrays, each of the plurality of memory arrays including a plurality of memory cells formed in a respective one of a plurality of metallization layers disposed over a substrate;
a plurality of first sense amplifiers, each of the plurality of first sense amplifiers and a corresponding one of the memory arrays formed in a respective one of the metallization layers; and
a plurality of multiplexers, each of the plurality of multiplexers, a corresponding one of the memory arrays, and a corresponding one of the first sense amplifiers formed in the respective one of the metallization layers.

2. The memory device of claim 1, wherein each of the plurality of multiplexers and the corresponding first sense amplifier are coupled to each other and formed in a boundary region of the respective one of the metallization layers.

3. The memory device of claim 1, further comprising:
a controller that is coupled to the plurality of multiplexers, configured to transmit a control signal indicative of one of the metallization layers, and formed over the substrate.

4. The memory device of claim 1, further comprising:
a second sense amplifier commonly coupled to the plurality of first sense amplifiers through a global bit line and formed over the substrate.

5. The memory device of claim 4, further comprising:
an input/output (I/O) circuit configured to receive an output from the second sense amplifier and formed over the substrate.

6. The memory device of claim 1, further comprising:
a plurality of word line rows formed in each of the plurality of metallization layers,
wherein a subset of the plurality of word line rows in multiple ones of the metallization layers are commonly coupled to a word line decoder.

7. The memory device of claim 6, wherein the word line decoder is formed over the substrate.

8. The memory device of claim 1, wherein each of the plurality of memory cells includes a transistor and a capacitor.

9. The memory device of claim 1, wherein the transistor and the capacitor are formed in multiple ones of the plurality of metallization layers.

10. A memory device, comprising:
a first memory array including a plurality of first memory cells that are disposed in a first one of a plurality of metallization layers disposed over a substrate;
a first sense amplifier also disposed in the first metallization layer, and configured to sense first data bits respectively stored in a subset of the first memory cells that are arranged along at least one column of the first memory array; and
a first multiplexer also disposed in the first metallization layer, and configured to provide the first sensed data bits to a common sense amplifier upon receiving a first control signal indicative of the first metallization layer, wherein the common sense amplifier is formed along a major surface of the substrate.

11. The memory device of claim 10, wherein the first sense amplifier and first multiplexer are coupled to each other and disposed in a boundary region of the first metallization layer.

12. The memory of claim 10, further comprising:
a second memory array including a plurality of second memory cells that are disposed in a second one of the plurality of metallization layers disposed over the first memory array;
a second sense amplifier also disposed in the second metallization layer, and configured to sense second data bits respectively stored in a subset of the second memory cells that are arranged along at least one column of the second memory array;
a second multiplexer also disposed in the second metallization layer, and configured to provide the second sensed data bits to the common sense amplifier upon receiving a second control signal indicative of the second metallization layer.

13. The memory of claim 12, wherein the second sense amplifier and second multiplexer are coupled to each other and disposed in a boundary region of the second metallization layer.

14. The memory device of claim 12, wherein the first multiplexer and the second multiplexer are coupled to the common sense amplifier through a global bit line.

15. The memory device of claim 12, wherein each of the plurality of first and the plurality of second memory cells includes a transistor and a capacitor that are respectively formed in multiple ones of the plurality of metallization layers.

16. The memory device of claim 12, further comprising:
a controller configured to send the first control signal to the first multiplexer, or the second control signal to the second multiplexer.

17. The memory device of claim 16, wherein the controller is disposed over the substrate.

18. A method of fabricating a memory device, comprising:
forming a plurality of memory arrays, wherein each of the plurality of memory arrays includes a plurality of memory cells formed in a respective one of a plurality of metallization layers disposed over a substrate;
forming a plurality of first sense amplifiers, wherein each of the plurality of first sense amplifiers and a corresponding one of the memory arrays are formed in a respective one of the metallization layers; and
forming a plurality of multiplexers, wherein each of the plurality of multiplexers, a corresponding one of the memory arrays, and a corresponding one of the first sense amplifiers are formed in the respective one of the metallization layers.

19. The method of claim 18, further comprising:
forming a second sense amplifier over the substrate, wherein the second sense amplifier is commonly coupled to the plurality of first sense amplifiers through a global bit line.

20. The method of claim 18, further comprising:
forming a plurality of transistors over first ones of the plurality of metallization layers;
forming a plurality of capacitors over second ones of the plurality of metallization layers, wherein the plurality of capacitors are respectively coupled to first source/drain terminals of the plurality of transistors;
forming a plurality of bit lines over third ones of the plurality of metallization layers, wherein the plurality of bit lines are respectively coupled to second source/drain terminals of the plurality of transistors; and
forming a plurality of word lines over fourth ones of the plurality of metallization layers, wherein the plurality of word lines are respectively coupled to gates of the plurality of transistors.
